(19) United States
(12) Patent Application Publication
(10) Pub. No.: US 2023/0335977 A1
(43) Pub. Date: Oct. 19, 2023

(54) MOUNTING DEVICE AND METHOD FOR INSTALLATION OF A POWER LINE DEVICE BY UNMANNED AERIAL SYSTEMS

(71) Applicant: BEIROBOTICS LLC, Richmond, VA (US)

(72) Inventors: Michael Kenneth BEIRO, Richmond, VA (US); Chase Hamilton COBLE, North Chesterfield, VA (US); David Carson SCHUL, Richmond, VA (US)

(21) Appl. No.: 18/136,663

(22) Filed: Apr. 19, 2023

Related U.S. Application Data
(60) Provisional application No. 63/332,527, filed on Apr. 19, 2022.

(51) Int. Cl. H02G 1/02; B64C 39/02; G01R 31/08; G01R 1/04

(52) U.S. Cl. CPC H02G 1/02; B64C 39/024; G01R 31/085; G01R 1/04

(57) ABSTRACT

A system for performing work on electrical power lines and/or splices on electrical power lines includes an unmanned aerial vehicle (UAV), a power line device configured to connect to an electrical power line and/or a splice on an electrical power line, a support frame selectively releasably attached to the UAV, and a plurality of flexible dielectric attachment lines attaching the power line device to the support frame. Each of the attachment lines are attached to a corresponding attachment point on the support frame and a corresponding attachment point on the power line device.

### CROSS-REFERENCE TO RELATED APPLICATIONS

This application claims priority to U.S. Provisional Application Ser. No. 63/332,527, filed Apr. 19, 2022, the contents of which are incorporated herein by reference in their entirety.

### TECHNICAL FIELD

This invention relates generally to electric power lines and more particularly to systems and methods for installing devices on same.

### BACKGROUND

Currently unmanned aerial system (UAS) technologies have been deployed for use in the electric transmission and distribution (T&D) industry in several ways, including light detection and ranging (LIDAR), visual and infrared camera inspection, and in recent years have been utilized in contact with power lines for installations of products on grounded or distribution voltage hardware and contact measurements on transmission voltage lines. Installations have solely been achieved of products that are specially designed for use by a UAS, not of products already in use by the T&D industry which are largely manipulated and installed by hot sticks (e.g., overhead faulted circuit indicators (FCIs) to assist utilities in reducing outage minutes). It is with respect to these and other considerations that aspects and embodiments of the present invention are presented herein.

### SUMMARY

Described herein is a device to be installed on live power lines (such devices are referred to herein as power line devices, which generally include a class of monitoring devices that attach (typically via a spring-loaded clamping mechanism) to and remain connected or attached to a power line, so that one or more characteristics of the power line), a hot stick-mountable bracket for installing the same via hot stick, an assembly of a control bar and weighted guide rods, and systems and methods of installing such devices through the aforementioned components and a UAS carrying a Nonconductive Payload System (NPS).

In general, one innovative aspect of the subject matter described in this specification may be embodied in an apparatus or system that includes a deployment device releasably attached to a power line device at one or more points, wherein the power line device is configured to connect onto an electrical power line and/or a splice on the electrical power line, a support frame configured to be selectively and releasably coupled to an unmanned aerial vehicle (UAV), and at least one attachment line connecting the deployment device to the support frame.

These and other embodiments can each optionally include one or more of the following features.

In some embodiments of the invention, the power line device comprises a spring-loaded latch. In some embodiments of the invention, the spring-loaded latch is configured to connect the power line device onto the electrical power line and/or the splice based on a thrust movement upon the electrical power line.

In some embodiments of the invention, the at least one attachment line comprises three attachment lines. In some embodiments of the invention, the at least one attachment line comprises flexible dielectric connection lines.

In some embodiments of the invention, the deployment device includes a main bar, a mounting adapter, a crossbar affixed perpendicularly to the main bar via the mounting adapter, an installation adapter affixed to the crossbar via the mounting adapter, wherein the installation adapter comprises a hot stick attachment point, and a pair of guide rods attached to the main bar via a guide rod attachment bracket, wherein the deployment device is configured to attach to a power line device by the hot stick attachment point on the installation adapter and a corresponding attachment point on the power line device.

In some embodiments of the invention, the pair of guide rods comprises two parallel guide rods that are substantially equal in length and are separated by a distance of at least a width of a spring-loaded latch on the power line device. In some embodiments of the invention, at least one attachment line comprises a first, a second, and a third attachment line, the first attachment line is connected to a first end of the crossbar, the second attachment line is connected to a second end of the crossbar, and a third attachment line is connected a back end of the main bar. In some embodiments of the invention, the deployment device comprises at least one guide rod. In some embodiments of the invention, the at least one guide rod comprises a weight at a distal end of the guide rod, weighted material within the guide rod, or a combination thereof.

In some embodiments of the invention, the support frame further comprises a plurality of flexible dielectric support lines. In some embodiments of the invention, a length of each of the flexible dielectric support lines is based on an electromagnetic field of the electrical power line. In some embodiments of the invention, a length of each of the flexible dielectric support lines is adapted to be selected based on a voltage of the electrical power line.

In some embodiments of the invention, the apparatus comprises a nonconductive payload system (NPS). In some embodiments of the invention, the NPS comprises an upper frame, the lower frame, and the attachment lines. In some embodiments of the invention, the apparatus further includes the UAV.

In general, another innovative aspect of the subject matter described in this specification may be embodied in a deployment device that includes a main bar, a mounting adapter, a crossbar affixed perpendicularly to the main bar via the mounting adapter, an installation adapter affixed to the crossbar via the mounting adapter, wherein the installation adapter comprises a hot stick attachment point, and a pair of guide rods attached to the main bar via a guide rod attachment bracket, wherein the deployment device is configured to attach to a power line device by the hot stick attachment point on the installation adapter and a corresponding attachment point on the power line device, and wherein the power line device is configured to connect onto an energized electrical power line and/or a splice on the electrical power line.

These and other embodiments can each optionally include one or more of the following features.

In some embodiments of the invention, the pair of guide rods comprises two parallel guide rods that are substantially equal in length and are separated by a distance of at least a width of the spring-loaded latch on the power line device. In some embodiments of the invention, the power line device comprises a spring-loaded latch that is adapted to connect the power line device onto the electrical power line and/or the splice based on a thrust movement upon the power line.

In general, another innovative aspect of the subject matter described in this specification may be embodied in a method that may include the actions of attaching a power line device to an unmanned aerial vehicle (UAV) via a deployment device, wherein the deployment device comprises guide rods that extend below the power line device and is connected to the UAV via a nonconductive payload system (NPS), wherein the power line device includes a spring-loaded latch and is adapted to attach onto an energized electrical power line and/or a splice on the energized electrical power line. The process may further include the actions of piloting the UAV to a first position adjacent to and at an altitude that is higher than an energized electrical power line and/or a splice on the energized electrical power line upon which it is desired to attach the power line device at an installation location. The process may further include the actions of piloting the UAV to a second position from the first position based on determining that at least a portion of the guide rods is approximately abutting at or substantially near a desired installation location for the power line device, wherein the at least the portion of the guide rods is close to a distal end of the guide rods and is below the power line device. The process may further include the actions of reducing the altitude of the UAV to drop the power line device onto the energized electrical power line and/or the splice to engage a spring-loaded latch such that the power line device is latched onto the energized electrical power line and/or the splice by the spring-loaded latch. The process may further include the actions of increasing the altitude of the UAV to separate the power line device from the deployment device.

This summary is provided to introduce a selection of concepts in a simplified form that are further described below in the detailed description. This summary is not intended to identify key features or essential features of the claimed subject matter, nor is it intended to be used in isolation as an aid in determining the scope of the claimed subject matter.

### BRIEF DESCRIPTION OF THE DRAWINGS

The accompanying drawings, which are incorporated in and constitute a part of this specification, illustrate various embodiments of the present invention and, together with the general description of the invention given above, and the detailed description of the embodiments given below, serve to explain the embodiments of the invention. In the drawings, like reference numerals are used to indicate like parts in the various views.

FIG. 1 is a perspective view of a system for installing a power line device via a deployment device, in accordance with embodiments of the present invention.

FIGS. 2A-2D illustrate different views of a deployment device of the system of FIG. 1.

FIGS. 3A and 3B illustrate views of the system of FIG. 1 for installing a power line device onto an electrical power line via the deployment device.

### DETAILED DESCRIPTION

Certain terminology is used in the following description for convenience only and is not limiting. The words “lower,” “bottom,” “upper,” and “top” designate directions in the drawings to which reference is made. The words “inwardly,” “outwardly,” “upwardly” and “downwardly” refer to directions toward and away from, respectively, the geometric center of the device, and designated parts thereof, in accordance with the present disclosure. Unless specifically set forth herein, the terms “a,” “an” and “the” are not limited to one element, but instead should be read as meaning “at least one.” The terminology includes the words noted above, derivatives thereof and words of similar import.

The present invention relates, in some aspects and in accordance with some embodiments, to a device to be installed on live power lines (such devices are referred to herein as power line devices, which generally include a class of monitoring devices that attach (often via a spring-loaded clamping mechanism) to and remain attached to a power line, so that one or more characteristics of the power line), a hot stick-mountable bracket for installing the same via hot stick, an assembly of a control bar and weighted guide rods, and systems and methods of installing such devices through the aforementioned components and a UAS carrying a Nonconductive Payload System (NPS).

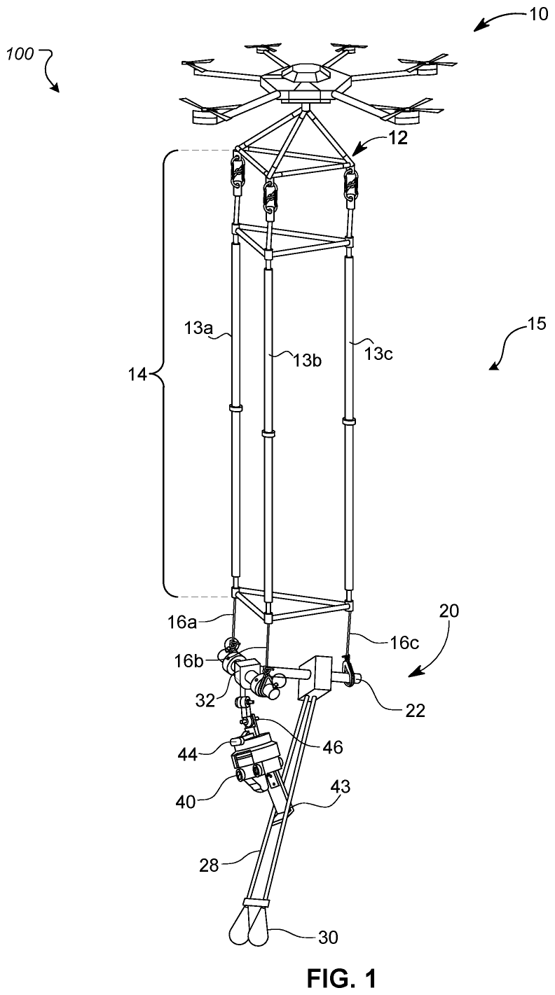

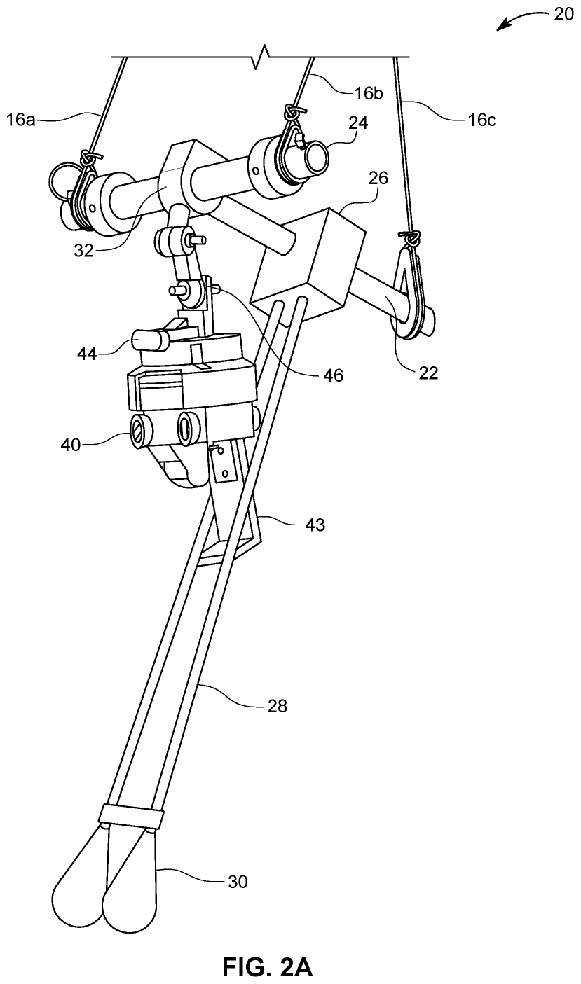

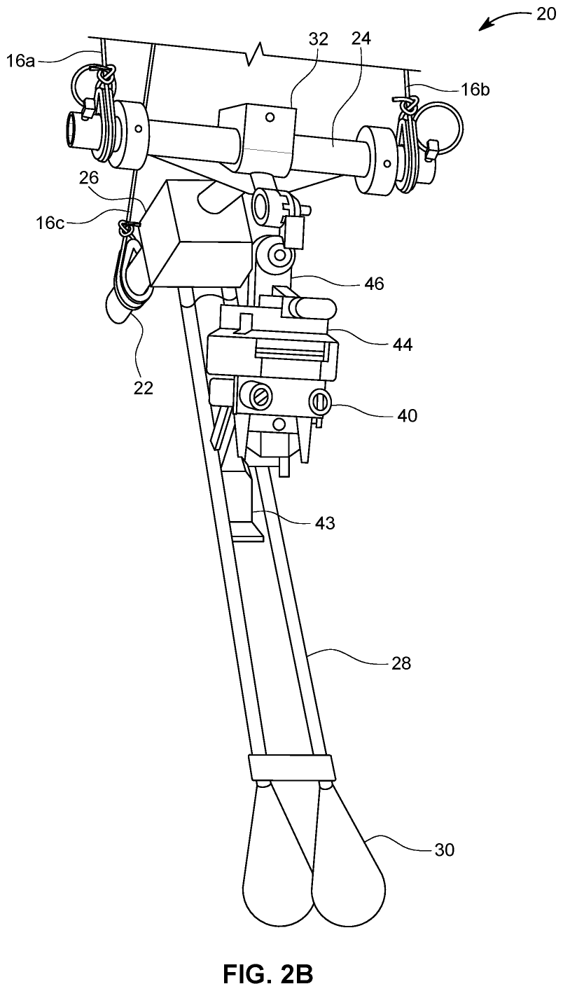

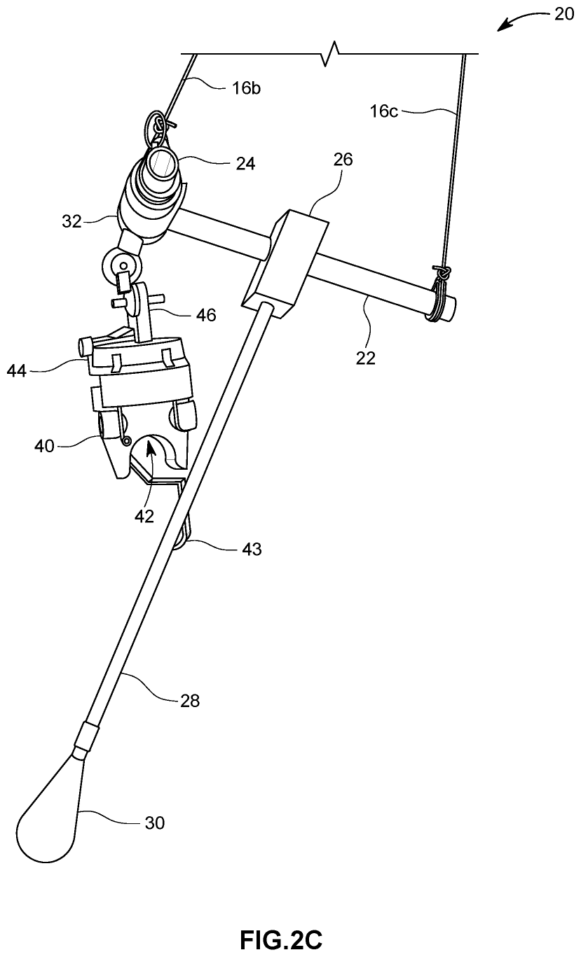

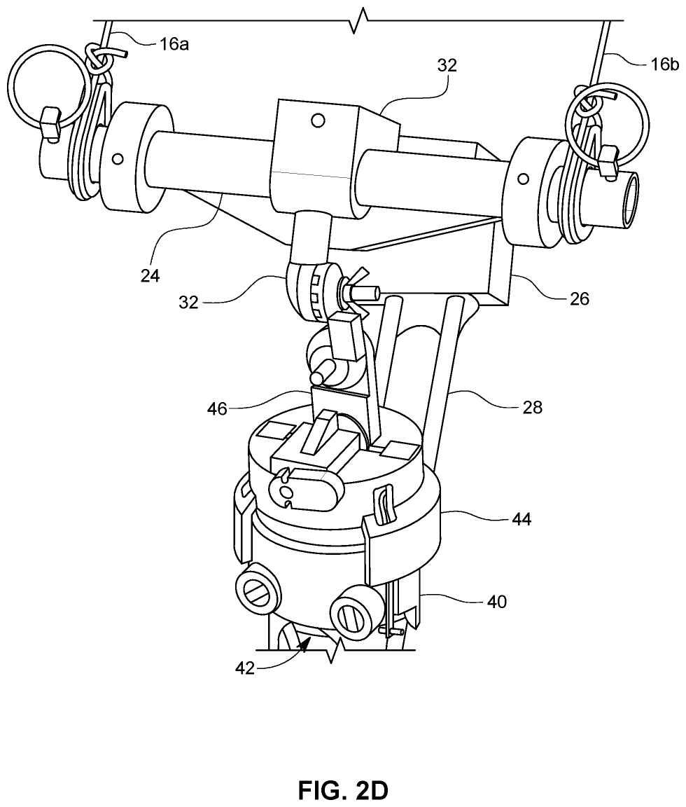

FIG. 1 illustrates a system 100 for installing a power line device 40 on a power line via a deployment device 20. FIGS. 2A-2D illustrate different views of the deployment device 20 for installing the power line device 40. The system 100 includes an unmanned aerial system (UAS) 10 and a NPS 15. The UAS 10 may be referred to as a drone, and sometimes referred to as an unmanned aerial vehicle (UAV). The NPS 15 includes an upper frame 12 that may be releasably attachable to the UAS 10 and a lower frame 14, and a deployment device 20 carrying the power line device 40 that is selectively attachable to the lower frame 14 of the NPS 15. For example, the UAS 10 and the NPS 15 enable the deployment device 20 and the power line device 40, which includes spring-loaded latch 43, to be efficiently carried to an active electrical power line and positioned for deployment, as described herein. Three attachment lines 16a, 16b, 16c extend from the lower end of the NPS 15 and are attachable to the deployment device 20. The lower frame 14 includes three dielectric support lines 13a, 13b, 13c that are connected between a lower and upper portion of the lower frame 14, and may be adjustable in length. Although three attachment lines 16a-c and three support lines 13a-c are shown, more or fewer lines may be used, however, fewer cables may not provide stable support for the UAS 10 or the power line device 40 during flight.

In some implementations, the power line device 40 may be selectively attachable to an installation adapter 44. The installation adapter 44 includes a hot stick attachment point 46 on an opposite side from where the power line device 40 attaches to the installation adapter 44. Conventionally, the power line device 40 may be installed on a power line by attaching the power line device 40 to the installation adapter 44, and then attaching the installation adapter 44 to a conventional hot stick (not shown) via the hot stick attachment point. A power line worker uses the hot stick to move the power line device 40 toward the power line until the power line enters the gap 42 defined in the power line device 40. When the power line is placed within the gap 42 and the power line device 40 is pushed against the power line, spring-loaded latch 43 is configured to quickly close via a spring-loaded mechanism such that the power line is secured into the gap 42 and the power line device 40 is secured on the power line. In some implementations, the spring-loaded latch 43 may require approximately 10 to 13 pounds of force to engage the locking mechanism, but the force required may vary based on the type of power line device 40 and/or spring-loaded latch 43 being utilized. The power line worker may then pull back on the hot stick and the installation adapter 44 separates from the power line device 40, thereby leaving the power line device 40 in position on the power line. The systems and methods of embodiments of the invention enable the power line device 40 (or the like) to be installed on an electrified power line without the use of a hot stick (as conventionally described herein) and without having a power line worker get close to the electrified power line, thereby greatly reducing the risk of injury or death of a power line worker.

The deployment device 20 includes a main bar 22 that runs generally front-to-back (as determined by the general forward flight direction of the UAS) with a crossbar 24 affixed generally perpendicularly to the main bar 22. The deployment device 20 is supported by the NPS by attaching one attachment line 16a, 16b to each end of the crossbar 24 and one attachment line 16c to the back end of the main bar 22 using any suitable mechanism or method of attachment.

A guide rod attachment bracket 26 is affixed to the main bar 22 and supports one or more guide rods 28 (two are illustrated) such that the guide rods 28 project downward and at an angle from the main bar 22. The guide rods 28 may include weights 30. As illustrated, the weights 30 are teardrop shaped weights and located at the distal ends of the guide rods 28. Additionally, or alternatively, in some embodiments different weighted elements may be used. For example, solid matter inside the guide rods 28 may be added such as solid copper rods for the guide rods 28. The weights 30 help stabilize the entire assembly during flight and the teardrop shapes may help minimize snagging on power lines or any other obstacles. The guide rod attachment bracket 26 is positioned on the main bar 22 to provide the desired position (described below) of the guide rods 28 relative to the power line device 40, as the positioning and angle of the guide rods 28 aids in the installation of the power line device on a power line. In some embodiments, it may be generally preferable that the guide rods 28 are long enough to extend past the power line device 40 to guide the power line device 40 into position to engage the power line. For the same reason, it may be preferable that the position and angle of the guide rods 28 may be such that the guide rods 28 run nearly tangent to the spring-loaded latch 43 on the power line device 40. In an exemplary embodiment, as illustrated, the guide rods 28 are two parallel rods of substantially equal in length that are separated by a distance of at least a width of the spring-loaded latch 43 on the power line device 40. In an exemplary embodiment, as illustrated, the guide rods 28 are at an angle of approximately at a range of 20 to 60 degrees from an approximate straight line from the ground to the UAS 10 during flight, although alternatively the angle may be less or greater depending on the power line device 40 and the angle needed to connect the spring-loaded latch 43. Additionally, or alternatively, in some implementations, propellers may be added to the deployment device 40 to assist in creating the necessary thrust or motion to trigger the spring-loaded latch 43.

The deployment device 20 includes a mounting adapter 32 for the power line device. The mounting adapter 32 may, as in the illustrated embodiment, also function as the connector between the main bar 22 and the crossbar 24. The mounting adapter 32 has a cooperative hot stick-type attachment point to engage with the hot stick attachment point 46 of the installation adapter 44.

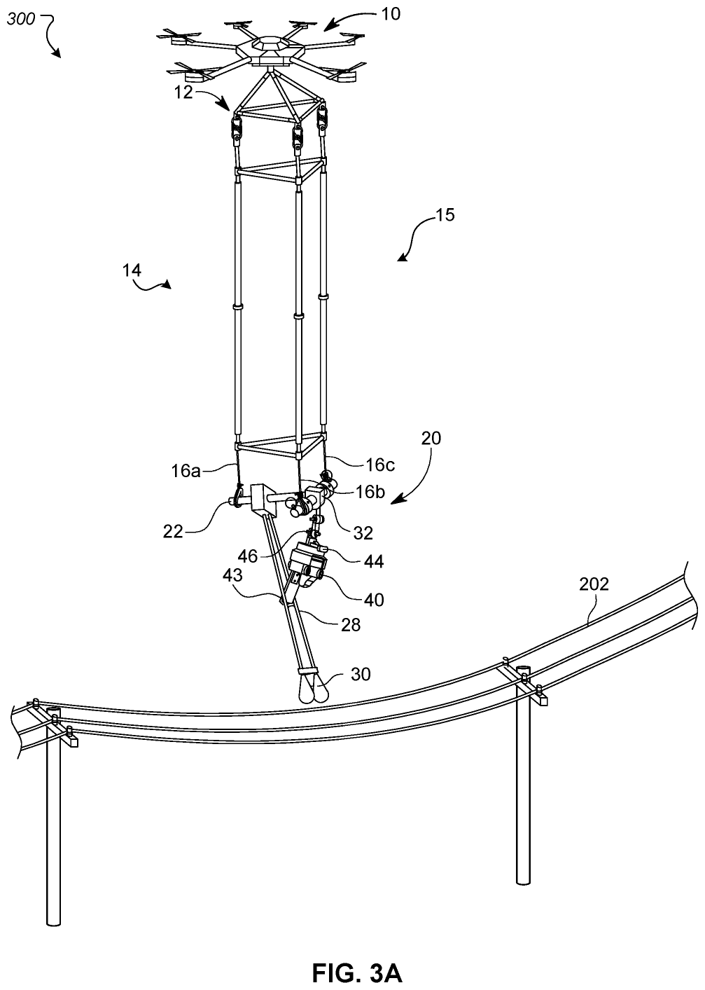

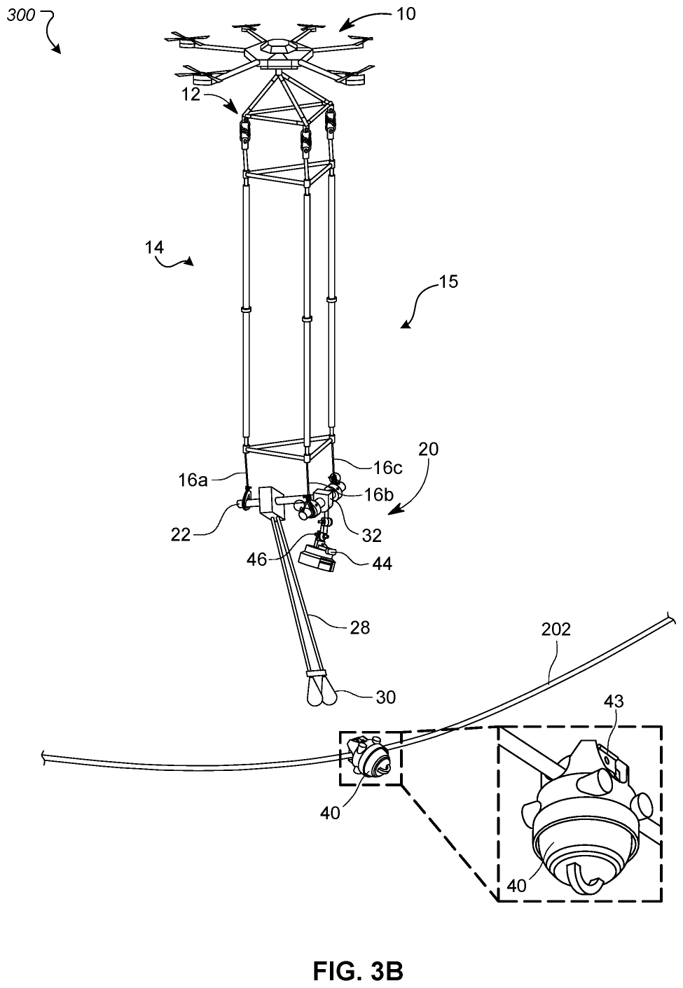

FIGS. 3A and 3B illustrate views of an operating environment 300 for installing a power line device 40 onto a power line 202. In particular, FIG. 3A illustrates the system 100 approaching the electrical power line 202 via the UAS 10, and positioning (e.g., preparing) to drop the power line device 40 to lock (e.g., clamp via spring-loaded latch 43) onto the power line 202. FIG. 3B illustrates the system 100 after connecting (e.g., latching, clamping, etc.) power line device 40, including the spring-loaded latch 43, to the power line 202 and the UAS 10 flying away from the area. The power line device 40 may be configured for performing work (e.g., contact inspection, repair, or any other suitable work tasks that may be performed) on an electrical power line 202 and/or a splice on the electrical power line 202.

Embodiments of the invention may further include methods for using a UAS 10 to deliver and land a tool or similar device (e.g., power line device 40) on an electrical power line and/or on a splice on an electrical power line, while the UAS 10 maintains flight and does not itself land on the power line and/or splice. Such methods may include some or all of the following steps. The airborne portion of the system (such as NPS 15 and UAS 10, as illustrated in FIGS. 1 and 3) may be assembled and readied for use. For the airborne portion (e.g., UAS 10 connected to the NPS 15), a support frame (e.g., upper frame 12) may be attached to a UAS 10 via a payload release mechanism, and a deployment device 20 may be attached to the lower frame 14 of the NPS 15 via a plurality of flexible dielectric attachment lines 16a, 16b, and 16c connecting the lower frame 14 to the deployment device 20. In some implementations, the plurality of flexible dielectric attachment lines 16a, 16b, and 16c may be dielectric hollow tubes. A power line device 40 may be attached to the installation adapter 44 of the deployment device 20. When airborne, the power line device 40 may be activated.

To install the power line device 40 (or the like) using the systems and methods of embodiments of the invention, the power line device 40 may be attached to the installation adapter 44, which in turn may be attached to the mounting adapter 32 of the deployment device 20. The deployment of device 20 may be attached to the attachment lines 16a-c of the NPS 15, and the upper frame 12 of the NPS 15 may be attached to the UAS 10. In other words, each of the attachment lines 16a-c are attached to a corresponding attachment point on the support frame (e.g., lower frame 14 and upper frame 12) of the NPA 15, and a corresponding attachment point on the power line device 40. The UAS 10 takes off and flies toward the installation location. The UAS 10 may be piloted to position the deployment device 20 such that the guide rods 28 contact the power line. The UAS 10 reduces thrust to guide and drop the power line device 40 onto the power line such that the power line enters the gap 42, activating the spring-loaded latching mechanism which clamps the device 40 to the power line. The UAS then increases thrust to disconnect the installation adapter 44 spring-loaded deadbolt from the power line device 40, completing the installation. In other words, the spring-loaded latch 43 may be configured to connect (e.g., attach, latch, etc.) the power line device 40 based on a thrust movement of the UAS to lower the power line device 40 onto an electrical power line and/or a splice on an electrical power line.

In some implementations, the spring-loaded latch 43 may require approximately 10 to 13 pounds of force to engage the locking mechanism, thus an amount of reduction of thrust by the operator to lower the UAS 10 may need to correlate to the amount of force needed to engage the spring-loaded latch 43. However, the force required, and thus the amount of reduction of thrust of the UAS 10, may vary based on the type of power line device 40, the spring-loaded latch 43, and the UAS 10 being utilized. In some implementations, the reduction of thrust for the UAS 10 required to engage the locking mechanism of the spring-loaded latch 43 may be determined by the operator of the UAS 10 (e.g., after practicing on a test line). Additionally, or alternatively, in some implementations, the reduction of thrust for the UAS 10 required to engage the locking mechanism of the spring-loaded latch 43 may be preprogrammed to a flight protocol of the UAS 10.

The UAS 10 may be piloted to a position adjacent to and higher than the electrical power line 202 and/or a splice on an electrical power line 202 upon which it is desired to perch and connect the power line device 40. The UAS 10 may be piloted laterally until the guide rods 28 of the deployment device 20 contact the power line and/or the splice. The altitude of the UAS 10 may be reduced to lower the power line device 40 onto the power line and/or the splice such that the power line device 40 may be perched or connected on the power line and/or the splice via the spring-loaded latch 43. The altitude of the UAS 10 may be further reduced to introduce slack into the support lines (e.g., the plurality of flexible dielectric support lines), which helps prevent small in-flight movements of the UAS 10 from pulling the power line device 40 off the line. The UAS 10 may also be moved laterally apart from the power line, as it may not be desirable to have the UAS 10 hover directly above the power line while the work is being performed, in case an emergency arises (described further below). While the power line device 40 is perched on the line and the UAS 10 is hovering near by and laterally apart from the power line, the power line device 40 may perform whatever action (e.g., inspection, repair, etc.) that it is designed to perform. If the power line device 40 needs to be repositioned on the power line to perform its work, the UAS 10 may be piloted appropriated to drag or lift and move the power line device 40 to a new position to continue/complete the work. In some implementations, the power line device 40 can be reconnected to the deployment device 20.

In an exemplary embodiment, an example process for utilizing the system 100 may include attaching a power line device to an unmanned aerial vehicle (UAV) via a deployment device, wherein the deployment device comprises guide rods that extend below the power line device and is connected to the UAV via a nonconductive payload system (NPS), wherein the power line device includes a spring-loaded latch and is adapted to attach onto an energized electrical power line and/or a splice on the energized electrical power line. The process may further include piloting the UAV to a first position adjacent to and at an altitude that is higher than an energized electrical power line and/or a splice on the energized electrical power line upon which it is desired to attach the power line device at an installation location. The process may further include piloting the UAV to a second position from the first position based on determining that at least a portion of the guide rods is approximately abutting at or substantially near a desired installation location for the power line device, wherein the at least the portion of the guide rods is close to a distal end of the guide rods and is below the power line device. The process may further include reducing the altitude of the UAV to drop the power line device onto the energized electrical power line and/or the splice to engage a spring-loaded latch such that the power line device is latched onto the energized electrical power line and/or the splice by the spring-loaded latch. The process may further include increasing the altitude of the UAV to separate the power line device from the deployment device.

If there is an emergency while the power line device 40 is perched on the power line 202, the UAS 10 pilot may activate a payload release mechanism to detach the support frame from the UAS 10. The support frame will fall to the ground and may pull the power line device 40 off the power line 202 so that the power line device may also fall to the ground (e.g., if not clamped on to the power line 202). The combined weight may be sufficient to pull the deployment device 20 off the line, but if the power line device 40 is connected (e.g., clamped) on the line when the payload release is activated, the power line device 40 may be disconnected from the installation adapter 44 and left on the line.

In some embodiments of the invention, a system (e.g., system 100) may be utilized for performing work (including contact inspection, repair, or any other suitable work tasks that may be performed) on an electrical power line and/or a splice on the electrical power line. The system may comprise an unmanned aerial vehicle (UAV) (e.g., UAS 10), a power line tool (e.g., power line device 40) adapted to perch on the power line and/or the splice, a support frame (e.g., upper frame 12 and lower frame 14) selectively releasably attached to the UAV, a plurality of flexible dielectric support lines as part of the support frame (e.g., support lines 13a-c), and a plurality of flexible dielectric attachment lines (e.g., attachment lines 16a-c) attaching the power line tool to the support frame. Although three attachment lines 16a-c are shown, although more or fewer may be used; however fewer cables may not provide stable support for the tool during flight). Each of the support attachment lines may be attached to a corresponding attachment point on the support frame (e.g., the lower portion of lower frame 14) and a corresponding attachment point on the power line tool (e.g., attachment points on the crossbar 24 or main bar 22).

The UAV may be any suitable remotely piloted aircraft, typically multi-rotor, with sufficient payload capacity to carry the support frame, support lines, and power line tool. In the illustrated embodiments, UAV comprises a main body and six rotors supported by corresponding rotor support arms (any suitable number of rotors may be used). As is conventionally known, the UAV may be controlled in flight by an operator or pilot using a controller (not illustrated). The UAV may have retractable landing gear (not illustrated).

In the illustrated embodiments, a support frame (e.g., upper frame 12) may be generally pyramidal, providing two front attachment points and one rear attachment point for the support lines. However, any suitable support frame structure may be used. Having at least three attachment points provides more stability to the tool during flight than having only one or two attachment points. The number, position, and arrangement of the attachment points may vary. The support lines may be attached to the support frame in any suitable manner or with any suitable mechanism and may be removably attached or fixedly attached. The support frame may be constructed from any suitable material or combination of materials that is sufficiently strong, sufficiently rigid, and sufficiently lightweight, such as carbon fiber or any suitable polymer.

A support frame (e.g., upper frame 12) includes a UAV attachment flange. The UAV attachment flange may be generally aligned with the central front-to-back axis of the support frame. The UAV attachment flange may be configured to mate with a payload release mechanism that may be mounted to the underside of the main body of the UAV to enable releasable attachment of the support frame to the UAV. In one exemplary embodiment of the invention, the payload release mechanism comprises any suitable payload release mechanism. The payload release mechanism may have a movable pin that selectively engages with the hole in the UAV attachment flange. The pin engages with the hole in the UAV attachment flange to couple the support frame and the UAV during normal operation of the system and disengages to release the support frame from the UAV at the end of a mission or in an emergency. The thickness of the UAV attachment flange may be selected to enable the support frame to pitch relative to the UAV but to somewhat limit yaw and roll of the support frame relative to the UAV as the UAV pitches, yaws, and rolls during flight (some yaw and roll of the support frame is acceptable to limit yaw and roll of the support frame from transferring to the UAV). The payload release mechanism may be controlled by the UAV operator.

The support lines (e.g., support lines 13a-c or attachment lines 16a-c) may comprise any suitably strong and flexible material, such as ropes (natural or synthetic), metallic cables, wires, etc. In one exemplary embodiment of the invention, the support lines comprise Hy-Dee-Brait Hot Rope from Yale Cordage. The material selected for the support lines is typically a non-conductive (dielectric) material to prevent electricity from being conducted up the support lines to the UAV. Although it may be possible to electrically shield the critical components of the UAV, it may be desirable that the length of the support lines be long enough to maintain a sufficient distance between the UAV and the power line to prevent damage to the UAV from the electromagnetic fields surrounding such high-voltage power lines. In this regard, the length of the support lines may be selected based on the voltage of the power line upon which the tool (e.g., power line device 40, or the like) is to be perched (based on the live-line work approach distances set forth in the National Electrical Safety Code). For example, if the voltage of the power line is 145 kilovolts (kV), then the length of the support lines (e.g., support lines 13a-c) should be at least five feet, four inches to maintain the desired spacing between the UAV and the power line. As another example, if the voltage of the power line is 362 kV, then the length of the support lines should be at least thirteen feet, six inches. Additionally, the UAV should be a minimum of twenty feet from the highest structure point (which may be a shield or static line) when working on a line. In most cases there is some charge in the shield line which runs above the energized phases, so the UAV should be kept above those.

Importantly, in systems and methods of embodiments of the invention, the power line tool that is suspended from the UAV may be lowered onto a power line and/or splice while the UAV hovers safely apart from the power line and preferably outside of the electromagnetic field. The power line tool may comprise any suitable tool for inspecting, repairing or otherwise performing work on a power line, splice, or other component of a high voltage electrical power system. In the illustrated embodiment, the power line tool comprises a contact inspection tool, such as an OhmStik™ from SensorLink Corporation.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. An apparatus comprising:
a deployment device releasably attached to a power line device at one or more points, wherein the power line device is configured to connect onto an electrical power line and/or a splice on the electrical power line;
a support frame configured to be selectively and releasably coupled to an unmanned aerial vehicle (UAV); and
at least one attachment line connecting the deployment device to the support frame.

2. The apparatus of claim 1, wherein the power line device comprises a spring-loaded latch.

3. The apparatus of claim 2, wherein the spring-loaded latch is configured to connect the power line device onto the electrical power line and/or the splice based on a thrust movement upon the electrical power line.

4. The apparatus of claim 1, wherein the at least one attachment line comprises three attachment lines.

5. The apparatus of claim 1, wherein the at least one attachment line comprises flexible dielectric connection lines.

6. The apparatus of claim 1, wherein the deployment device comprises:
a main bar;
a mounting adapter;
a crossbar affixed perpendicularly to the main bar via the mounting adapter;
an installation adapter affixed to the crossbar via the mounting adapter, wherein the installation adapter comprises a hot stick attachment point; and
a pair of guide rods attached to the main bar via a guide rod attachment bracket,
wherein the deployment device is configured to attach to a power line device by the hot stick attachment point on the installation adapter and a corresponding attachment point on the power line device.

7. The apparatus of claim 6, wherein the pair of guide rods comprises two parallel guide rods that are substantially equal in length and are separated by a distance of at least a width of a spring-loaded latch on the power line device.

8. The apparatus of claim 6, wherein:
at least one attachment line comprises a first, a second, and a third attachment line;
the first attachment line is connected to a first end of the crossbar;
the second attachment line is connected to a second end of the crossbar; and
a third attachment line is connected a back end of the main bar.

9. The apparatus of claim 1, wherein the deployment device comprises at least one guide rod.

10. The apparatus of claim 9, wherein the at least one guide rod comprises a weight at a distal end of the guide rod, weighted material within the guide rod, or a combination thereof.

11. The apparatus of claim 1, wherein the support frame further comprises a plurality of flexible dielectric support lines.

12. The apparatus of claim 11, wherein a length of each of the flexible dielectric support lines is based on an electromagnetic field of the electrical power line.

13. The apparatus of claim 11, wherein a length of each of the flexible dielectric support lines is adapted to be selected based on a voltage of the electrical power line.

14. The apparatus of claim 1, wherein the apparatus comprises a nonconductive payload system (NPS).

15. The apparatus of claim 14, wherein the NPS comprises an upper frame, the lower frame, and the attachment lines.

16. The apparatus of claim 1, further comprising the UAV.

17. A deployment device comprising:
a main bar;
a mounting adapter;
a crossbar affixed perpendicularly to the main bar via the mounting adapter;
an installation adapter affixed to the crossbar via the mounting adapter, wherein the installation adapter comprises a hot stick attachment point; and
a pair of guide rods attached to the main bar via a guide rod attachment bracket,
wherein the deployment device is configured to attach to a power line device by the hot stick attachment point on the installation adapter and a corresponding attachment point on the power line device, and
wherein the power line device is configured to connect onto an energized electrical power line and/or a splice on the electrical power line.

18. The deployment device of claim 17, wherein the pair of guide rods comprises two parallel guide rods that are substantially equal in length and are separated by a distance of at least a width of the spring-loaded latch on the power line device.

19. The deployment device of claim 17, wherein the power line device comprises a spring-loaded latch that is adapted to connect the power line device onto the electrical power line and/or the splice based on a thrust movement upon the power line.

20. A method comprising:
attaching a power line device to an unmanned aerial vehicle (UAV) via a deployment device, wherein the deployment device comprises guide rods that extend below the power line device and is connected to the UAV via a nonconductive payload system (NPS), wherein the power line device comprises a spring-loaded latch and is adapted to attach onto an energized electrical power line and/or a splice on the energized electrical power line;
piloting the UAV to a first position adjacent to and at an altitude that is higher than an energized electrical power line and/or a splice on the energized electrical power line upon which it is desired to attach the power line device at an installation location;
piloting the UAV to a second position from the first position based on determining that at least a portion of the guide rods is approximately abutting at or substantially near a desired installation location for the power line device, wherein the at least the portion of the guide rods is close to a distal end of the guide rods and is below the power line device;
reducing the altitude of the UAV to drop the power line device onto the energized electrical power line and/or the splice to engage a spring-loaded latch such that the power line device is latched onto the energized electrical power line and/or the splice by the spring-loaded latch; and
increasing the altitude of the UAV to separate the power line device from the deployment device.
